(19) United States
(12) Patent Application Publication
(10) Pub. No.: US 2023/0072310 A1
(43) Pub. Date: Mar. 9, 2023

(54) METHOD FOR FORMING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: Jingwen LU, Hefei (CN)

(21) Appl. No.: 17/846,147

(22) Filed: Jun. 22, 2022

Related U.S. Application Data
(63) Continuation of application No. PCT/CN2021/130555, filed on Nov. 15, 2021.

(30) Foreign Application Priority Data
Sep. 6, 2021 (KR) 202111038805.1

(51) Int. Cl. H01L 27/108

(52) U.S. Cl. CPC H01L 27/10805; H01L 27/10891

(57) ABSTRACT

The embodiments of the disclosure provide a method for forming a semiconductor structure and a semiconductor structure. The method includes that: a base is provided, in which the base includes a Word Line (WL) trench with a stepped side wall, and a width of a top of the WL trench is greater than a width of a bottom of the WL trench; an insulating structure is formed on the side wall and the bottom wall of the WL trench; and a WL structure is formed in the WL trench where the insulating structure is formed.

### CROSS-REFERENCE TO RELATED APPLICATIONS

The disclosure is a continuation application of International Patent Application No. PCT/CN2021/130555, filed on Nov. 15, 2021, which claims priority to Chinese Patent Application No. 202111038805.1, filed on Sep. 6, 2021 and entitled “METHOD FOR FORMING SEMICONDUCTOR STRUCTURE AND SEMICONDUCTOR STRUCTURE”. The disclosures of International Patent Application No. PCT/CN2021/130555 and Chinese Patent Application No. 202111038805.1 are hereby incorporated by reference in their entireties.

### BACKGROUND

A semiconductor device such as a Dynamic Random Access Memory (DRAM) includes a plurality of memory cells, a Word Line (WL) and a Bit Line (BL). Each memory cell includes a transistor and a capacitor. The WL is configured to turn on/turn off the transistor in the memory cell. When the transistor is turned on, both ends of the transistor are turned on, and the potential on the BL is transmitted to the corresponding capacitor.

The DRAM also includes a Node Contact (NC) and a Bit Line Contact (BLC). When the DRAM is designed, it is necessary to set a lower surface of the NC and a lower surface of the BLC to be in the same horizontal plane as an upper surface of the WL. However, when the DRAM is actually prepared, the lower surface of the NC and the lower surface of the BLC cannot be completely in the same horizontal plane as the upper surface of the WL. For example, a side wall of the NC and a side wall of the BLC will overlap with a side wall of the WL, and an overlap part where the side wall of the NC and the side wall of the BLC overlap with the side wall of the WL is called an overlap area, which will generate overlap capacitance or cause transistor leakage.

### SUMMARY

The disclosure relates to, but is not limited to, a method for forming a semiconductor structure and a semiconductor structure.

Embodiments of the disclosure provide a method for forming a semiconductor structure and a semiconductor structure.

According to a first aspect, the embodiments of the disclosure provide a method for forming a semiconductor structure, which includes the following operations.

A base is provided, in which the base includes a Word Line (WL) trench with a stepped side wall, and a width of a top of the WL trench is greater than a width of a bottom of the WL trench.

An insulating structure is formed on the side wall and a bottom wall of the WL trench.

A WL structure is formed in the WL trench where the insulating structure is formed.

According to a second aspect, the embodiments of the disclosure provide a semiconductor structure, which includes:

a base, in which the base includes a Word Line (WL) trench with a stepped side wall, and a width of a top of the WL trench is greater than a width of a bottom of the WL trench; and

an insulating structure formed on the side wall and a bottom wall of the WL trench, and a WL structure surrounded by the insulating structure.

### DETAILED DESCRIPTION

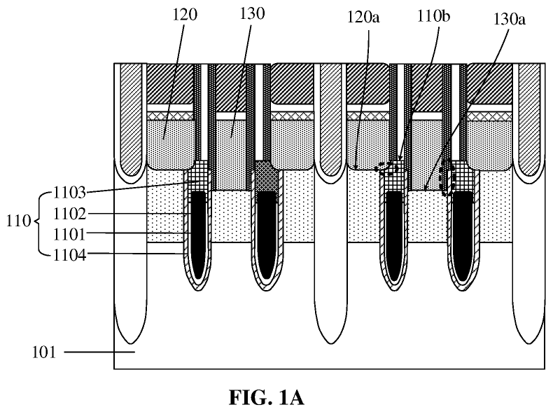

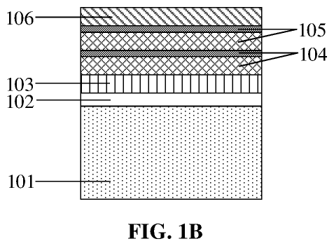

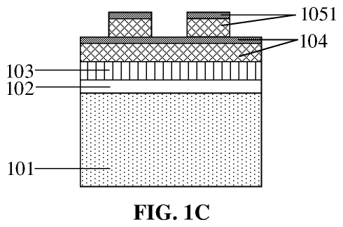

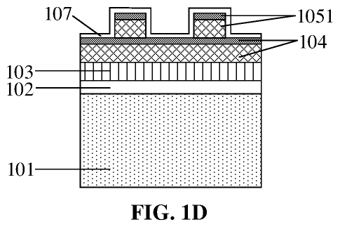

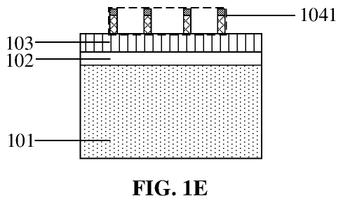

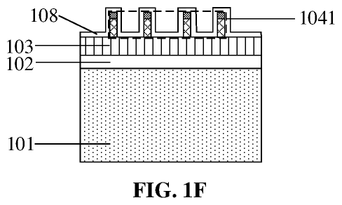

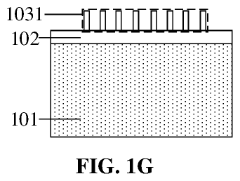

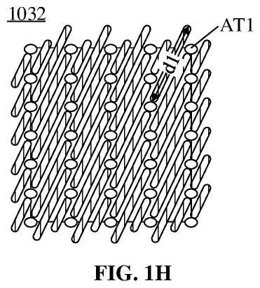

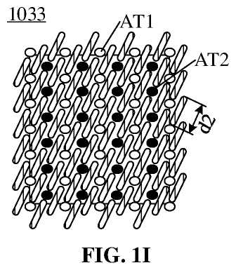

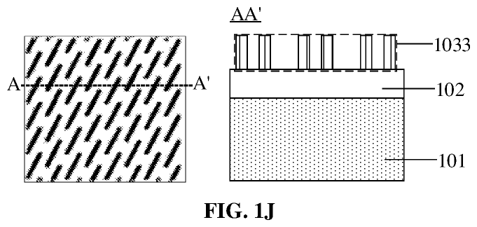

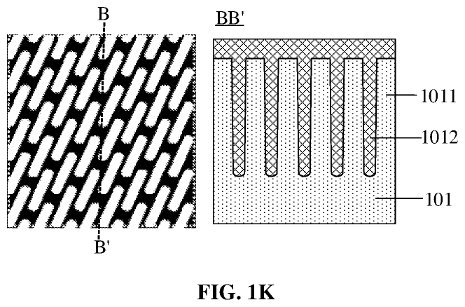

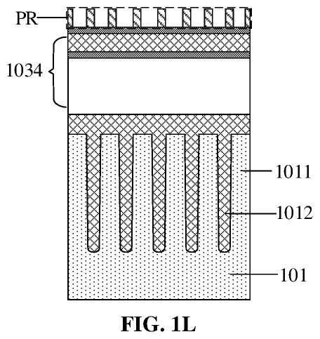

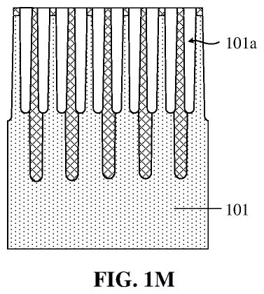

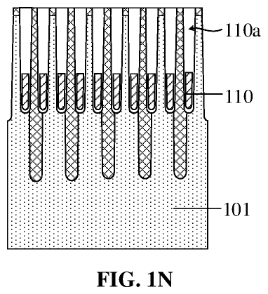

FIGS. 1A to FIG. IN are schematic diagrams of a process for forming a Word Line (WL) structure provided in the related art.

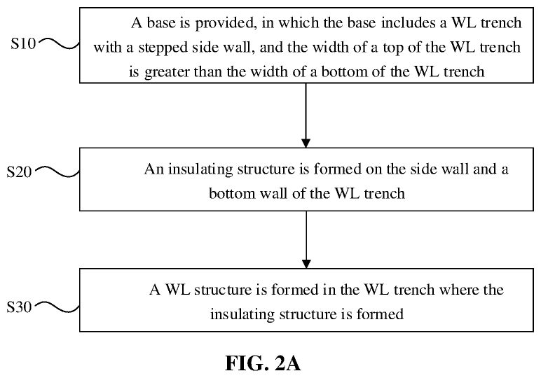

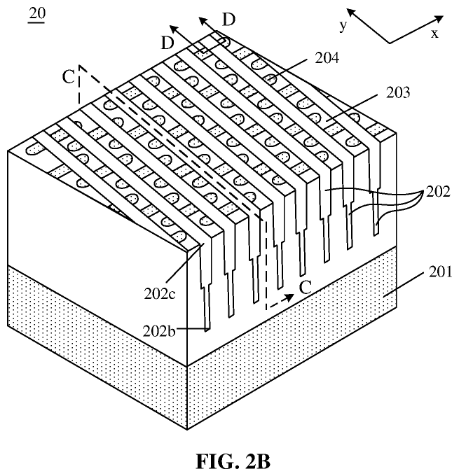

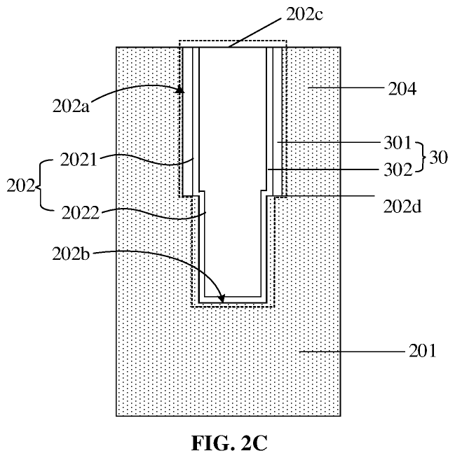

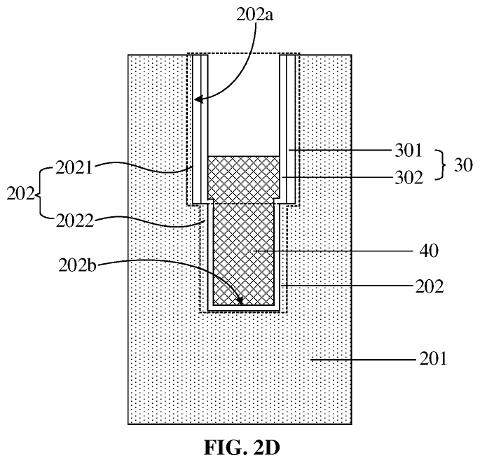

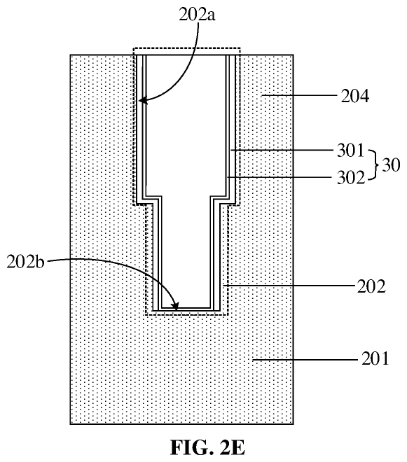

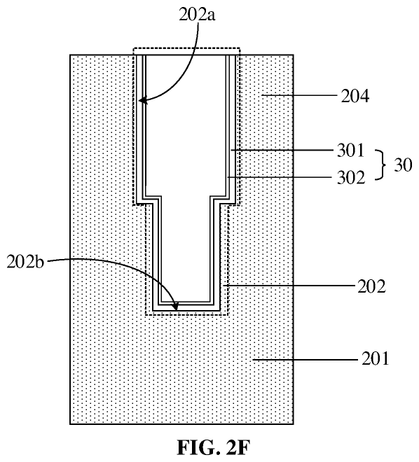

FIG. 2A is a flowchart of a method for forming a semiconductor structure according to an embodiment of the disclosure.

FIG. 2B to FIG. 2F are schematic diagrams of a process for forming a WL structure according to an embodiment of the disclosure.

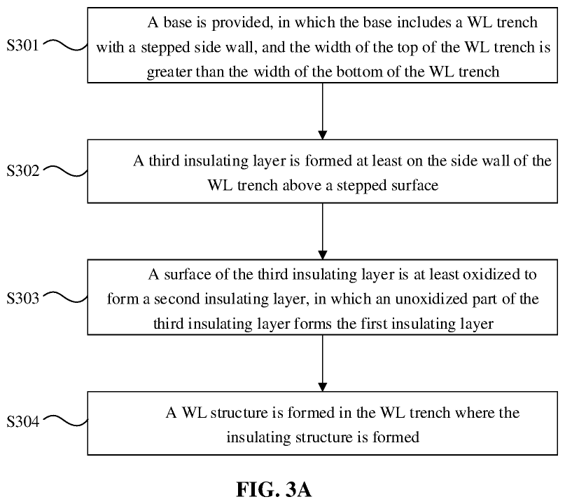

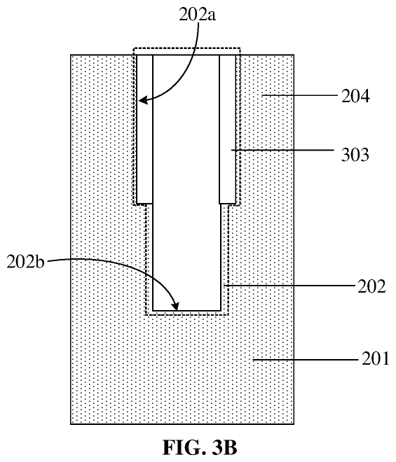

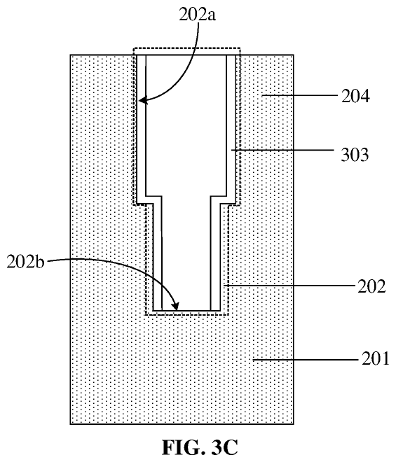

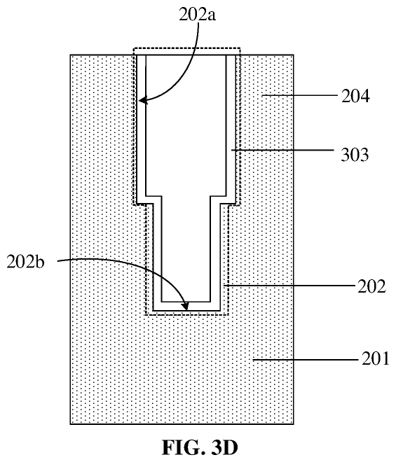

FIG. 3A is a flowchart of another method for forming a semiconductor structure according to an embodiment of the disclosure.

FIG. 3B to FIG. 3D are schematic diagrams illustrating the formation of a third insulating layer in a semiconductor structure according to an embodiment of the disclosure.

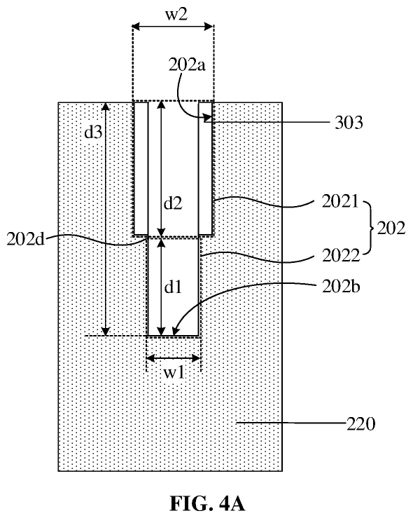

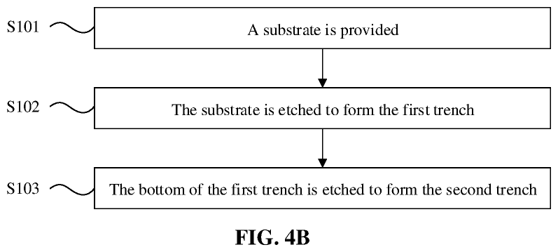

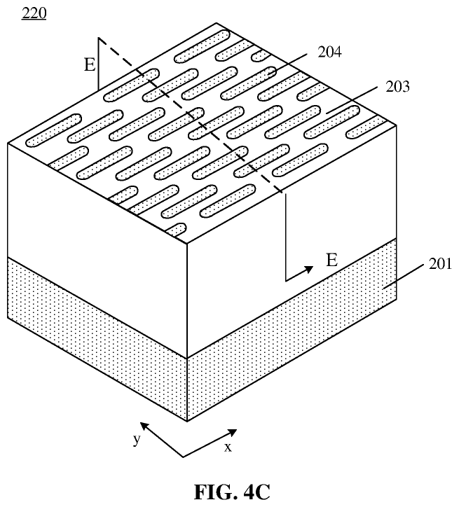

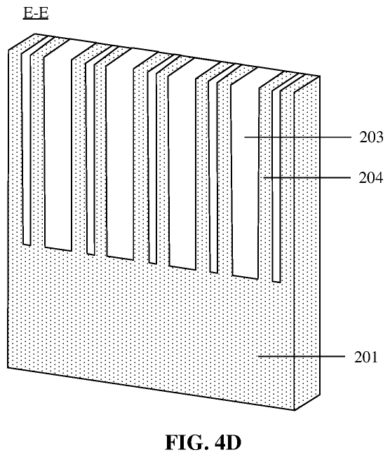

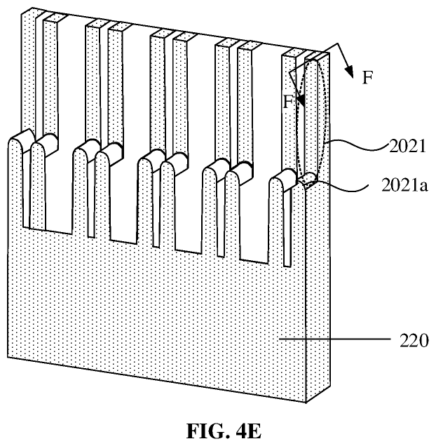

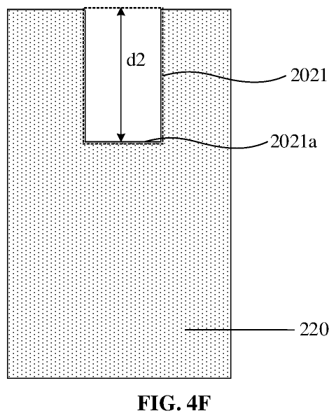

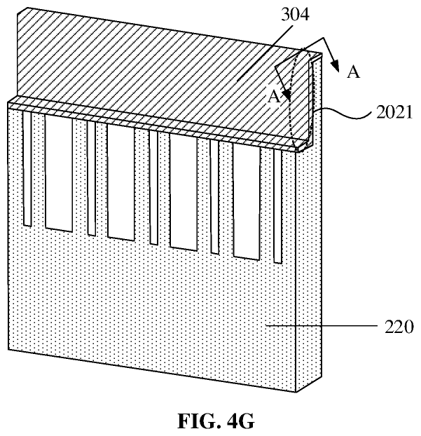

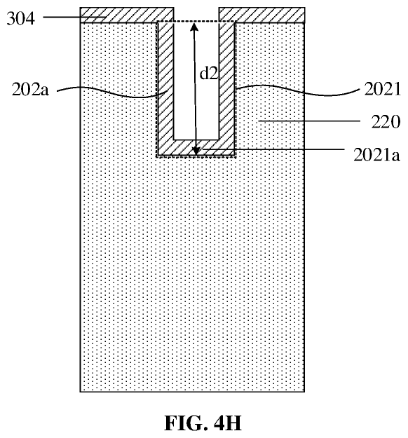

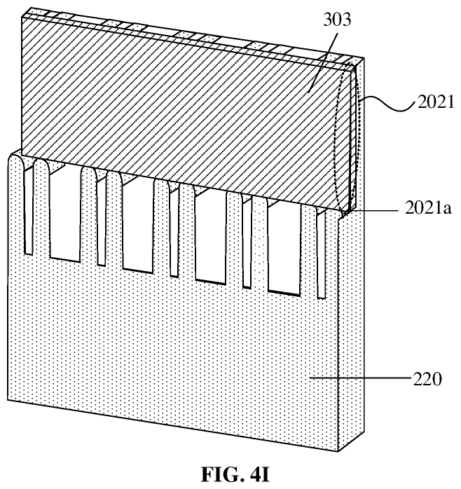

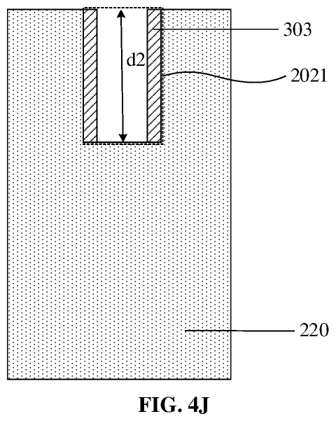

FIG. 4A is a schematic diagram of a WL trench according to an embodiment of the disclosure.

FIG. 4B is a flowchart of the operation of forming a WL trench in a method for forming a semiconductor structure according to an embodiment of the disclosure.

FIG. 4C to FIG. 4J are schematic diagrams of a process for forming a WL trench in a semiconductor structure according to an embodiment of the disclosure.

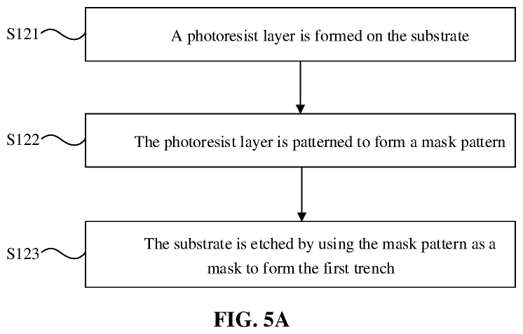

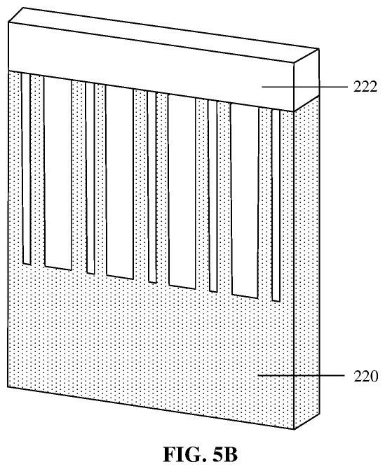

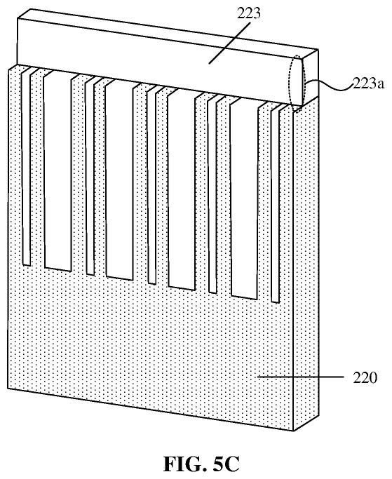

FIG. 5A is a flowchart of the operation of forming a first trench in a method for forming a semiconductor structure according to an embodiment of the disclosure.

FIG. 5B to FIG. 5C are schematic diagrams illustrating the formation of a first trench in a method for forming a semiconductor structure according to an embodiment of the disclosure.

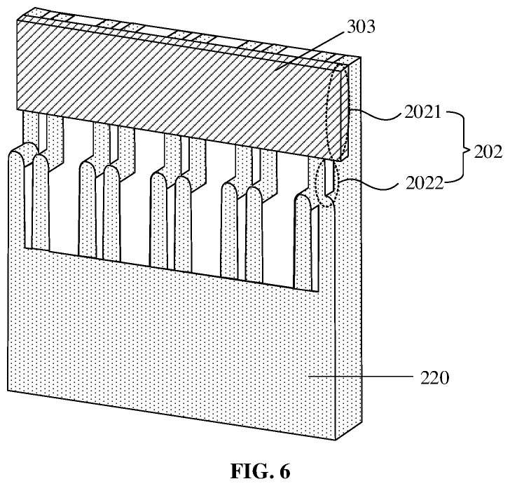

FIG. 6 is a schematic diagram illustrating the formation of a second trench in a method for forming a semiconductor structure according to an embodiment of the disclosure.

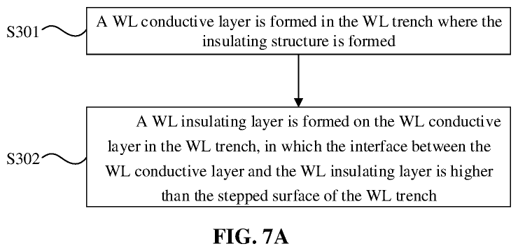

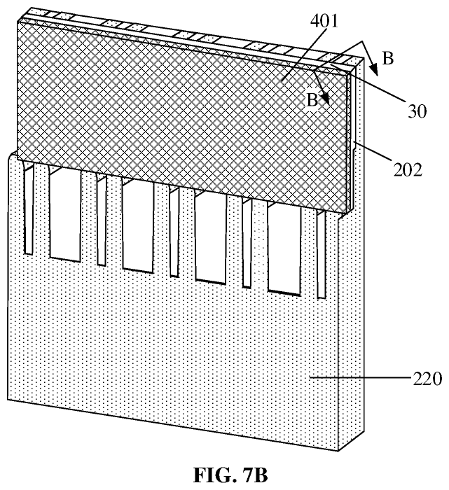

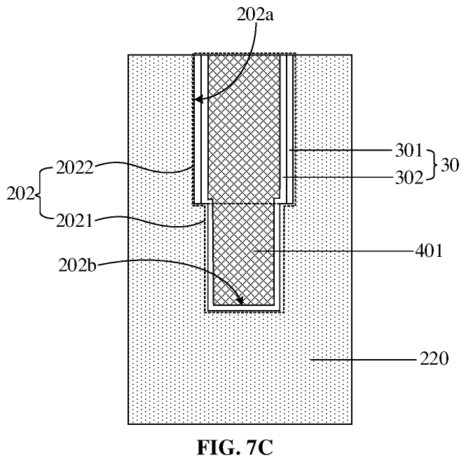

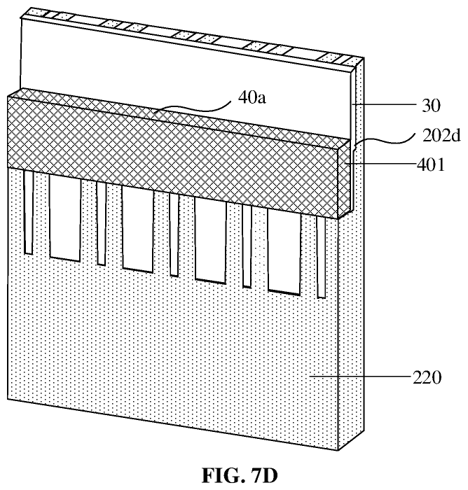

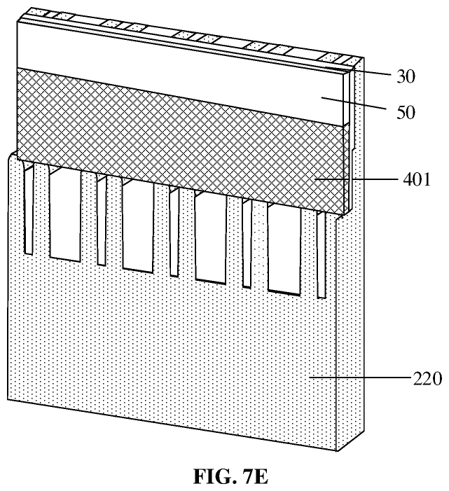

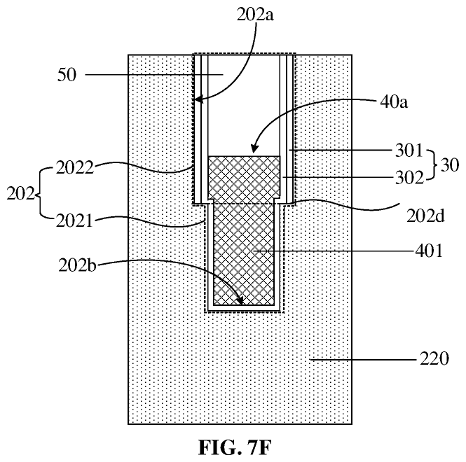

FIG. 7A is a flowchart of the operation of a WL structure in a method for forming a semiconductor structure according to an embodiment of the disclosure.

FIG. 7B to FIG. 7F are schematic diagrams illustrating the formation of a WL structure in a WL trench in a method for forming a semiconductor structure according to an embodiment of the disclosure.

Reference numerals of the figures are illustrated as follows.

20. base; 30. insulating structure; 401. WL conductive layer; 50. WL insulating layer; 120a. bottom surface of NC; 110b. top surface of WL structure; 130a. bottom surface of BCL; 100. base; 101. substrate; 102. barrier layer; 103. first mask layer; 104. first hard mask layer; 105. second hard mask layer; 106. photoresist layer; 107. first isolation layer; 108. second isolation layer; 110. WL structure; 120. NC; 130. BLC; 201. first substrate; 202. WL trench; 220. substrate; 222. photoresist layer; 223. mask pattern; 301. first insulating layer; 302. second insulating layer; 303. third insulating layer; 304. fourth insulating layer; 1011. active area; 1012. isolation layer; 1031. second mask layer; 1032. third mask layer; 1033. fourth mask layer; 1041. second hard mask pattern; 1051. first hard mask pattern; 1101. WL metal layer; 1011. active area; 1102. WL adhesive layer; 1103. WL protective layer; 1104. WL insulating layer; 204. active area; 203. isolation area; 2021. first trench; 2022. second trench; AT1. first photomask; AT2. second photomask; 110a. WL trench; 202a. side wall of WL trench; 202b. bottom wall of WL trench; 202c. top of WL trench; 2021a. bottom of first trench; 202d. stepped surface; and 40a. surface of WL conductive layer.

### DETAILED DESCRIPTION

In order to make the purposes, technical solutions, and advantages of the embodiments of the disclosure clearer, specific technical solutions of the disclosure will further be described below in combination with the drawings in the embodiments of the disclosure in detail. The following embodiments are adopted to describe the disclosure but are not intended to limit the scope of the disclosure.

In the following description, suffixes such as “module” or “unit” used to indicate elements are only used to facilitate the description of the disclosure, and have no specific meaning in themselves. Therefore, “module” or “unit” may be used in a mixed manner.

In order to better understand the technical solution provided by the embodiments of the present disclosure, the related art is introduced first.

With reference to FIG. 1A, in a semiconductor device (for example, a DRAM), the semiconductor structure includes a substrate 101, a Word Line (WL) structure 110, a Node Contact (NC) 120, and a Bit Line Contact (BLC) 130. Herein, the WL structure 110 includes a WL metal layer 1101, a WL adhesive layer 1102, a WL protective layer 1103, and a WL insulating layer 1104.

Below, a process for forming a semiconductor structure in the related art is described with reference to FIG. 1A to FIG. 1N.

With reference to FIG. 1B, a barrier layer 102, a first mask layer 103, a first hard mask layer 104, a second hard mask layer 105 and a photoresist layer 106 are successively formed on a surface of a substrate 101. The first mask layer 103 is configured to form a mask layer through which the substrate 101 is etched. The barrier layer 102 is configured to protect the substrate 101 when the first mask layer 103, the first hard mask layer 104 and the second hard mask layer 105 are subsequently etched. The photoresist layer 106 is configured to form a pattern through which the second hard mask layer 105 is etched. The photoresist layer 106 is exposed, developed and dissolved, and the second hard mask layer 105 is etched to form a first hard mask structure 1051 shown in FIG. 1C. Herein, the pattern of the first hard mask structure 1051 includes a plurality of parallel stripe patterns, and the patterns expose a part of a surface of the first hard mask layer 104.

With reference to FIG. 1D, a first isolation layer 107 is deposited on a surface of the first hard mask structure 1051 and the part of the surface of the first hard mask layer 104 exposed by the first hard mask structure 1051. The first isolation layer 107 is etched back to form a first isolation structure (not shown in the figure). The first hard mask layer 104 is etched through the back-etched first isolation structure to form a second hard mask structure 1041 shown in FIG. 1E. The patterns of the second hard mask structure 1041 are also parallel stripe patterns, and the patterns expose a part of a surface of the first mask layer 103.

With reference to FIG. 1F, a second isolation layer 108 is deposited on a surface of the second hard mask structure 1041 and a surface of the first mask layer 103. The second isolation layer 108 is etched back to form a second isolation structure (not shown in the figure). The first mask layer 103 is etched by using the second isolation structure as a mask layer to form a second mask layer 1031 shown in FIG. 1G. The pattern of the second mask layer 1031 (initial mask pattern) also includes a plurality of parallel stripe patterns. Herein, the processes shown in FIG. 1D and FIG. 1E and the processes shown in FIG. 1F and FIG. 1G both adopt Self-aligned Double Patterning (SADP) technology.

With reference to FIG. 1G to FIG. II, the initial mask pattern in the second mask layer 1031 shown in FIG. 1G is clipped through a first photomask AT1 including a first preset pattern, to form a third mask layer 1032 with an initial active pattern shown in FIG. 1H. The third mask layer 1032 with the initial active pattern is clipped through a second photomask AT2 including a second preset pattern, to form a fourth mask layer 1033 with an active area pattern shown in FIG. H. Herein, the active area pattern is the pattern of the finally formed active area.

With reference to FIG. 1J, the substrate 101 and the barrier layer 102 are etched through the fourth mask layer 1033 to form active areas 1011 shown in FIG. 1K in the substrate 101. Silicon dioxide (SiO₂) is deposited between adjacent active areas 1011 and on the surfaces of the active areas 1011 to form an isolation layer 1012 to isolate any two adjacent active areas 1011 of the active areas 1011 from each other. Herein, the active area 1011 is configured to form an active device such as a transistor.

With reference to FIG. 1L, a part of the active area 1011 and a part of the isolation layer 1012 are etched through a Photo Resist (PR) and a mask layer 1034, to form a substrate 101 including a WL trench 110a shown in FIG. 1M. With reference to FIG. 1N, a WL structure 110 is formed in the WL trench 110a, and the WL structure 110 is configured to control turn-on or turn-off of the active device.

Next, other structures for forming a semiconductor structure such as the NC 120 and the BLC 130 are formed, to finally form the semiconductor structure shown in FIG. 1A.

The NC 120 is configured to electrically connect a source/drain area to other parts of the semiconductor structure. The BLC 130 is configured to electrically connect the active area to a Bit Line (BL) structure. The material of the NC 120 may be a conductive material containing silicon, with low resistance, for example, one or more of amorphous silicon or polysilicon. The material of the BLC 130 may be a conductive material containing silicon. For example, the material of the BLC 130 may be the same as the material of the NC 120.

Theoretically, when a semiconductor structure is designed, with reference to FIG. 1A, a bottom surface 120a of the NC 120 or a bottom surface 130a of the BLC 130 shall be at the same horizontal plane as a top surface 110b of the WL structure 110. However, when the semiconductor structure is actually prepared, the bottom surface 120a of the NC 120 or the bottom surface 130a of the BLC 130 cannot be completely in the same horizontal plane as the top surface 110b of the word line structure 110 due to the influence of process precision, etc. In this case, a part where the side wall of the NC 120 or the side wall of the BLC 130 overlaps with the side wall of the WL structure 110 in the vertical direction is called an overlap area (with reference to a dotted box in shown FIG. 1A). The strong electric field generated by the overlap area may cause electric leakage or generate overlap capacitance. In other words, in the semiconductor structure of the DRAM, the active area is configured to form the transistor, and the WL structure 110 is configured to control turn-on/turn-off of the transistor. The WL structure 110 and a gate-drain overlap area of a drain area in the transistor may generate a large Gate Induced Drain Leakage (GIDL).

In order to solve the above problem, with reference to FIG. 2A, the embodiments of the disclosure provide a method for forming a semiconductor structure, which includes the following operations.

At S10, a base is provided, in which the base includes a WL trench with a stepped side wall, and the width of a top of the WL trench is greater than the width of a bottom of the WL trench.

Here, the base may be a Silicon (Si) substrate, a Germanium (Ge) substrate, a Silicon-Germanium (SiGe) substrate, a gallium arsenide substrate, a ceramic substrate, a quartz substrate, or a glass substrate applied to a display, and may also include a plurality of layers, such as a Silicon-On-Insulator (SIO) substrate, or a Germanium-On-Insulator (GOI) substrate.

A WL trench may be formed in the base. Herein, the WL trench is configured to form a WL structure, to control turn-on or turn-off of an active device in the base.

The side wall of the WL trench may be stepped. Herein, the side wall may include at least one step, for example, one step or at least two steps. The number of steps is not limited in the embodiment of the present disclosure.

Taking one step included on the side wall as an example for description, the stepped WL trench may be formed by two etching processes. For example, a trench (which may be understood as a first trench) above a step surface may be formed by first of the two etching processes, and then the bottom of the first trench may be etched by second of the two etching processes to form a trench (which may be understood as a second trench) below the step surface. It is to be noted that the above, for the convenience of description, takes one step included on the side wall as an example for description. According to the forming processes, those skilled in the art may learn that the side wall includes at least two steps.

At S20, an insulating structure is formed on the side wall and a bottom wall of the WL trench.

Here, the insulating structure covers a surface of the WL trench, and the insulating structure may include at least one insulating layer, for example, one layer or at least two layers. The material of the insulating structure may be silicon dioxide, silicon oxycarbide, etc.

In some embodiments, the insulating structure may be formed by a deposition process. The deposition process includes any of the following processes: Chemical Vapor Deposition (CVD) process, Physical Vapor Deposition (PVD) process, Atomic Layer Deposition (ALD) process, and any other suitable deposition process.

At S30, a WL structure is formed in the WL trench where the insulating structure is formed.

In some embodiments, the WL structure may at least include a WL conductive layer, and the material of the WL conductive layer may include metal and polysilicon. Herein, the metal material may include, but is not limited to, any combination of the conductive materials such as Wolframium (W), Cobalt (Co), Copper (Cu) and Aluminum (Al). Generally, the polysilicon covers a top surface of a metal, and is configured to inhibit oxygen from entering a WL metal layer where the metal is located, to improve the conductivity of the WL conductive layer.

In some embodiments, a WL adhesive layer may be formed between the WL metal layer and the insulating structure. The WL adhesive layer covers the surfaces except the top surface of the WL metal layer, and the WL adhesive layer is configured to improve the adhesion between the WL metal layer and the insulating structure. The material of the WL adhesive layer may be titanium nitride.

In the embodiment of the disclosure, the side wall of the WL trench is set to be stepped, and the width of the top of the WL trench is larger than the width of the bottom of the WL trench. Then, the insulating structure is formed on the side wall and a bottom wall of the WL trench. The shape of the WL trench is changed, so that electric leakage caused or overlap capacitance generated by an overlap area in the related art is reduced by the insulating structure in the WL trench.

FIG. 2B to FIG. 2D are schematic diagrams of a process for forming a semiconductor structure according to an embodiment of the disclosure. Further description is made below to operations S10 to S30 with reference to FIG. 2B to FIG. 2D.

With reference to FIG. 2B, a base 20 includes a first substrate 201, a plurality of active areas 204 located on the first substrate 201, and isolation areas 203 for isolating adjacent active areas 204 from each other. The plurality of active areas 204 are stripe structures extending in a second direction x.

Herein, the first substrate 201 may be a silicon substrate, a SOI substrate, a germanium substrate, a GOI substrate, a SiGe substrate or an epitaxial thin-film substrate obtained by performing a selectivity epitaxial growth process.

The isolation area 203 may be formed by forming a trench in the base 20 and then filling the trench with an isolation material. The material of the isolation area 203 may include silicon nitride or silicon oxide, etc. The base 20 further includes a WL trench 202 with a stepped side wall, and the side wall includes one step. The WL trench 202 penetrates through the active area 204 and the isolation area 203. The WL trench 202 extends along a third direction y, and a plurality of WL trenches 202 are parallel to each other. Herein, the width of a top 202c of the WL trench 202 is greater than the width of a bottom wall 202b of the WL trench 202.

The structure of FIG. 2C is obtained by cutting FIG. 2B along D-D. With reference to FIG. 2C, an insulating structure 30 is deposited on the side wall 202a and the bottom wall 202b of the WL trench 202. After the insulating structure 30 is formed, a WL structure 40 surrounded by the insulating structure 30 shown with reference to FIG. 2D is formed by deposition.

Generally speaking, the base 20 may include a top surface at a front surface and a bottom surface at a back surface opposite to the front surface. The direction perpendicular to the top surface and the bottom surface of the base is defined as the first direction, ignoring the flatness of the top surface and the bottom surface. In the direction of the top surface and the bottom surface of the base (that is, a plane in which the base is located), a second direction and a third direction intersecting with each other (for example, perpendicular to each other) are defined. For example, the direction in which the WL trench extends may be defined as the first direction, and the plane direction of the base may be determined based on the second direction and the third direction. The first direction is perpendicular to the second direction and the third direction, respectively. In the embodiment of the disclosure, the second direction is defined as an x-axis direction, the third direction is defined as a y-axis direction, and the angle between the second direction x and the third direction y is not limited in the embodiment of the disclosure.

In some embodiments, S20 includes the following operations.

At S201, an insulating structure is conformally formed on the side wall and the bottom wall of the WL trench. Herein, the thickness of the insulating structure at the top of the side wall is greater than the thickness of the insulating structure at the bottom of the side wall.

Here, the insulating structure is conformally formed on the side wall and the bottom wall of the WL trench. That is, the insulating structure has the same shape as the WL trench. For example, based on the shape of the WL trench, the insulating structure is formed in the WL trench by way of deposition and other processes, so that the shape of a surface of the insulating structure on a side thereof close to the WL trench is the same as the shape of the side wall and the bottom wall of the WL trench.

In the embodiment of the disclosure, since the width of the top of the WL trench is greater than the width of the bottom wall of the WL trench, and the insulating structure is conformal with the side wall and the bottom wall of the WL trench, the thickness of the insulating structure at the top of the side wall of the WL trench is enabled to be greater than the thickness of the insulating structure at the bottom of the side wall of the WL trench by controlling the thickness of the insulating structure. In brief, the insulating structure provided by the embodiment of the present disclosure is a structure with a thick top and a thin bottom. In the case where the insulating structure is a gate oxide layer, the gate oxide layer is also a structure with a thick top and a thin bottom. That is, the thickness of the gate oxide layer at the top of the side wall of the WL trench is greater than the thickness of the gate oxide layer at the bottom of the side wall of the WL trench.

Since the insulation effect of the insulating layer in the insulating structure corresponding to the thick part is better than the insulation effect of the insulating layer in the insulating structure corresponding to the thin part, the capacitance between the WL structure and other structures can be effectively reduced. When the above semiconductor structure is configured to form a DRAM, since a portion of the WL structure located in the active area also serves as a gate of the transistor, the above semiconductor structure may improve the on-off speed of the transistor and reduce the phenomenon of transistor leakage.

The above operation S201 may be understood with reference to FIG. 2C.

With reference to FIG. 2C, the side wall 202a and the bottom wall 202b of the WL trench 202 are conformal with the insulating structure 30. Since the width of the top 202c of the WL trench 202 is greater than the width of the bottom wall 202b of the WL trench 202, it may be implemented that the thickness of the insulating structure 30 located at the top of the side wall 202a is greater than the thickness of the insulating structure 30 at the bottom of the side wall 202a as shown with reference to FIG. 2C.

With reference to FIG. 2C, in some embodiments, the insulating structure 30 may include a first insulating layer 301 and a second insulating layer 302.

The first insulating layer 301 covers at least the side wall of the WL trench 202 above a stepped surface 202d of the WL trench 202.

The second insulating layer 302 covers a surface of the first insulating layer 301 and a surface of the WL trench 202 not covered by the first insulating layer 301.

Here, the surface of the WL trench 202 includes the side wall 202a and the bottom wall 202b of the WL trench 202.

In some embodiments, with reference to FIG. 2C, FIG. 2E and FIG. 2F, the side wall 202a of the WL trench 202 may be divided into an upper half and a lower half with the stepped surface 202d as a boundary. The first insulating layer 301 at least covers the side wall of the WL trench 202 above the stepped surface, including the following cases.

In the first case, with reference to FIG. 2C, the first insulating layer 301 covers the side wall 202a of the WL trench 202 above the stepped surface 202d. In other words, the first insulating layer 301 covers the upper half of the side wall 202a. The first insulating layer 301 does not cover the side wall 202a of the WL trench 202 below the stepped surface 202d and the bottom wall 202b of the WL trench 202. In other words, the first insulating layer 301 does not cover the lower half of the side wall 202a.

In the second case, with reference to FIG. 2E, the first insulating layer 301 covers the entire side wall 202a of the WL trench 202. That is, the first insulating layer 301 covers the side wall 202a of the WL trench 202 above the stepped surface 202d and the side wall 202a of the WL trench 202 below the stepped surface 202d. In other words, the first insulating layer 301 does not cover the bottom wall 202b of the WL trench 202.

In the third case, with reference to FIG. 2F, the first insulating layer 301 covers the entire side wall 202a and the bottom wall 202b of the WL trench 202. That is, the first insulating layer 301 covers the side wall 202a of the WL trench 202 above the stepped surface 202d, the side wall 202a of the WL trench 202 below the stepped surface 202d and the bottom wall 202b of the WL trench 202. In other words, the first insulating layer 301 covers the entire surface of the WL trench 202.

It is to be noted that the area of the first insulating layer 301 covering the surface of the WL trench 202 is not limited in the embodiment of the disclosure.

Here, the material of the first insulating layer may be different from the material of the second insulating layer, and correspondingly, the dielectric constant of the first insulating layer may be different from the dielectric constant of the second insulating layer. For example, the material of the first insulating layer may be silicon oxycarbide (SiCO), the material of the second insulating layer may be silicon dioxide (SiO₂), and the dielectric constant of SiCO (k1=4.1) is greater than the dielectric constant of SiO₂ (k2=3.9).

In some embodiments, two insulating layers of different materials, which are a first insulating layer and a second insulating layer, respectively, may be deposited in the WL trench. In other embodiments, an insulating layer of one material may be deposited in the WL trench, and then a surface of the insulating layer is oxidized by oxidation treatment. Herein, the unoxidized part of the insulating layer is the first insulating layer, and the oxidized part of the insulating layer is the second insulating layer.

In this case, since the dielectric constant corresponding to the material of the first insulating layer is different from the dielectric constant corresponding to the material of the second insulating layer, the insulating layer with higher dielectric constant may be equivalent to a thicker insulating layer with lower dielectric constant, which makes the insulating structure have better insulation effect, thus effectively reducing the capacitance between the WL structure and other structures. When the above semiconductor structure is configured to form a DRAM, since a portion of the WL structure located in the active area also serves as a gate of the transistor, the above semiconductor structure may improve the on-off speed of the transistor and reduce the phenomenon of transistor leakage.

In some embodiments, with reference to FIG. 2C and FIG. 2F, the thickness of the first insulating layer 301 is greater than the thickness of the second insulating layer 302.

In practical application, the material of the insulating structure 30 may be SiCO. After the insulating structure 30 is subjected to oxidization treatment, the unoxidized SiCO is the first insulating layer 301, and the oxidized SiCO is the second insulating layer 302.

When the insulating structure is oxidized, the oxide layer is quite thin. Therefore, the thickness of the first insulating layer is greater than the thickness of the second insulating layer, thus implementing two insulating layers made of two different materials, improving the insulation effect of the insulating structure and reducing the capacitance between the WL structure and other structures.

The embodiments of the disclosure further provide a method for forming a semiconductor structure. As shown in FIG. 3A, the method includes the following operations.

At S301, a base is provided, in which the base includes a WL trench with a stepped side wall, and the width of the top of the WL trench is greater than the width of the bottom of the WL trench.

Here, S301 is the same as S10, and may be understood with reference to S10.

At S302, a third insulating layer is formed at least on the side wall of the WL trench above a stepped surface.

Here, the material of the third insulating layer may be SiCO, and the third insulating layer may be formed by deposition.

At S303, a surface of the third insulating layer is at least oxidized to form a second insulating layer, in which an unoxidized part of the third insulating layer forms the first insulating layer.

Here, the surface of the third insulating layer refers to a surface of the third insulating layer that is not in contact with the WL trench. The manner of oxidizing the third insulating layer may include any of the following: dry oxygen oxidation, wet oxygen oxidation, water vapor oxidation and any other suitable oxidation process.

In some embodiments, S303 includes the following operations.

In a first case that the third insulating layer covers the side wall of the WL trench above the stepped surface and does not completely cover the surface of the WL trench, a surface of the WL trench not covered by the third insulating layer and a surface of the third insulating layer are oxidized to form a second insulating layer, and an unoxidized part of the third insulating layer forms the first insulating layer.

In a second case that the third insulating layer covers the entire side wall of the WL trench and does not completely cover the surface of the WL trench, a surface of the WL trench not covered by the third insulating layer and a surface of the third insulating layer are oxidized to form a second insulating layer, and an unoxidized part of the third insulating layer forms the first insulating layer.

In a third case that the third insulating layer completely covers the surface of the WL trench, a surface of the third insulating layer is oxidized to form a second insulating layer. An unoxidized part of the third insulating layer forms the first insulating layer.

At S304, a WL structure is formed in the WL trench where the insulating structure is formed.

Here, S304 is the same as S30, and may be understood with reference to S30.

In the embodiment of the disclosure, two insulating layers made of two different materials are implemented by way of oxidization, thus improving the insulation effect of the insulating structure and reducing the capacitance between the WL structure and other structures.

S302 and S303 are described below with reference to FIG. 3B and FIG. 3D.

With reference to FIG. 3B, a third insulating layer 303 is formed on the side wall of the WL trench 202 above the stepped surface and does not completely cover a surface of the WL trench 202, in which the surface of the third insulating layer 303 refers to the surface of the third insulating layer 303 that is not in contact with the WL trench 202. When the third insulating layer 303 is oxidized, oxidizing gas first contacts uncovered partial surface of the WL trench 202 not covered by the third insulating layer 303 and the surface of the third insulating layer 303, and then first oxidizes the surface of the WL trench 202, not covered by the third insulating layer and the surface of the third insulating layer 303, to form the second insulating layer 302 shown in FIG. 2C, and the unoxidized part of the third insulating layer 303 forms the first insulating layer 301 shown in FIG. 2C.

With reference to FIG. 3C, the third insulating layer 303 covers the entire side wall 202a of the WL trench 202, but does not completely cover the surface of the WL trench 202 (the bottom wall 202b of the WL trench 202 is not covered). Similarly, during the oxidation treatment, the oxidizing gas first contacts the surface of the third insulating layer 303 and the bottom wall 202b of the WL trench 202, to form the second insulating layer 302 shown in FIG. 2E, and the unoxidized part of the third insulating layer 303 forms the first insulating layer 301 shown in FIG. 2E.

With reference to FIG. 3D, the third insulating layer 303 completely covers the surface of the WL trench 202, that is, the third insulating layer 303 covers the side wall 202a of the WL trench 202 and the bottom wall 202b of the WL trench 202. Similarly, during the oxidation treatment, the oxidizing gas first contacts the surface of the third insulating layer 303 and then oxidizes the surface of the third insulating layer 303, to form the second insulating layer 302 shown in FIG. 2F, and the unoxidized part of the third insulating layer 303 forms the first insulating layer 301 shown in FIG. 2F.

In some embodiments, with reference to FIG. 4A, the WL trench 202 includes a first trench 2021 and a second trench 2022 which are stacked onto one another in the depth direction of the WL trench 202. Herein, the width w2 of the first trench 2021 is greater than the width w1 of the second trench 2022, and the interface between the first trench 2021 and the second trench 2022 is a stepped surface 202d of the WL trench 202.

Here, the stacked arrangement of the first trench 2021 and the second trench 2022 means that the depth of the first trench 2021 is d2, the depth of the second trench 2022 is d1, and the depth of the WL trench 202 is d3, in which d3=d1+d2. That is, a bottom surface of the first trench 2021 is a top surface of the second trench 2022.

In some embodiments, the depth d2 of the first trench 2021 is ⅓ of the depth d3 of the WL trench 202. Thus, when an insulating structure is deposited in the WL trench, the thicker insulating layer in the insulating structure corresponding to the first trench is made long enough, thus facilitating improving the insulation effect of the insulating layer overlapped with a WL conductive layer after the WL conductive layer is subsequently arranged.

In this case, S302 “the third insulating layer is formed at least on the side wall of the WL trench above the stepped surface” includes the following operations.

At S302a, a third insulating layer is formed on a side wall of the first trench.

S302a is described below with reference to FIG. 4A.

With reference to FIG. 4A, a third insulating layer 303 is formed on a side wall of the first trench 2021. Herein, the thickness of the third insulating layer 303 may be equal to half of the width of the first trench minus the width of the second trench. After the surface of the third insulating layer 303 and the surface of the WL trench 202 not covered by the third insulating layer 303 are oxidized, an insulating structure 30 shown in FIG. 2C is formed. Herein, the unoxidized part of the third insulating layer forms a first insulating layer 301 in the insulating structure 30. The surface of the third insulating layer 303 and the oxidized part of the surface of the WL trench 202 not covered by the third insulating layer 303 form a second insulating layer 302 in the insulating structure 30. The first insulating layer 301 covers the side wall of the first trench 2021. The second insulating layer 302 covers the first insulating layer 301 and the surface of the second trench 2022.

In some embodiments, S10 “a base is providing” includes the following operations shown in FIG. 4B.

At S101, a substrate is provided.

At S102, the substrate is etched to form the first trench.

Here, the substrate may be etched by dry etching technology or wet etching technology, such as reactive ion etching technology and plasma etching technology.

Correspondingly, S302a “the third insulating layer is formed on the side wall of the first trench” includes the following operations.

At S321, a fourth insulating layer is formed in the first trench and on the substrate.

Herein, the fourth insulating layer is formed by a deposition process. The deposition process includes any of the following: Chemical Vapor Deposition (CVD), Physical Vapor Deposition (PVD), Atomic Layer Deposition (ALD) and any other suitable deposition process.

Exemplarily, since the thickness of a deposited layer formed by ALD is extremely uniform and the consistency thereof is extremely excellent, the fourth insulating layer is deposited by ALD. The material of the fourth insulating layer may be a material with a large dielectric constant, such as silicon oxycarbide (SiCO), and the dielectric constant k1 of SiCO is equal to 4.1. In this case, the thickness of SiCO deposited by ALD ranges from about 3 to 8 nanometers (nm).

At S322, the fourth insulating layer on the substrate and at the bottom of the first trench is removed, and the fourth insulating layer on the side wall of the first trench is retained to form the third insulating layer.

In some embodiments, the fourth insulating layer on the substrate and at the bottom of the first trench is removed by a dry etching process, and the fourth insulating layer on the side wall of the first trench is retained to form the third insulating layer.

At S103, the bottom of the first trench is etched to form the second trench.

S101 to S103 are described below with reference to FIG. 4A to FIG. 4F.

With reference to FIG. 4C, a substrate 220 includes a first substrate 201, and an active area 204 and an isolation area 203, which are located on the first substrate 201. A plurality of active areas 204 are separated from each other, and the isolation area 203 is formed by filling a gap between the active areas 204.

The arrangement of the substrate 220 may refer to the arrangement of the above substrate 20 (a structure with the WL trench 202 removed).

FIG. 4D is a three-dimensional schematic diagram obtained by cutting FIG. 4C along E-E. For a clearer explanation, description is performed below based on FIG. 4D.

With reference to FIG. 4E, the substrate 220 is etched to form a first trench 2021.

FIG. 4F is a schematic diagram obtained by cutting FIG. 4E along F-F and corresponding to a complete first trench. Herein, the height of the first trench 2021 is d2.

The bottom 2021a of the first trench 2021 is etched to form a second trench 2022 shown in FIG. 4A.

The above operations S321 to S322 are described below with reference to FIG. 4G to FIG. 4J.

With reference to FIG. 4G, a fourth insulating layer 304 is formed in the first trench 2021 and on the substrate 220.

FIG. 4H is a schematic diagram obtained by cutting FIG. 4G along A-A and corresponding to a complete first trench. With reference to FIG. 4H, the fourth insulating layer 304 on the substrate 220 and at the bottom 2021a of the first trench 2021 is removed, and the fourth insulating layer 304 on the side wall 202a of the first trench 2021 is retained to form the third insulating layer 303 shown in FIG. 4I and FIG. 4J.

In some embodiments, S102 “the substrate is etched to form the first trench” includes the following operations shown in FIG. 5A.

At S121, a photoresist layer is formed on the substrate.

Here, the photoresist refers to a corrosion-resistant etching film material, the solubility of which changes through irradiation or radiation of ultraviolet light, an electron beam, an ion beam, an X-ray, etc. The photoresist is sensitive to light, including components such as photosensitive resin, sensitizer and solvent. In the process of photolithography, the photoresist is used as an anti-corrosion coating material.

At S122, the photoresist layer is patterned to form a mask pattern.

Here, the operation that the photoresist layer is patterned refers to exposing and developing the photoresist layer and dissolving a part of the photoresist layer. The undissolved part of the photoresist layer forms the mask pattern, and a first window in the mask pattern is a hollow pattern.

At S123, the substrate is etched by using the mask pattern as a mask to form the first trench.

S121 to S123 are described below with reference to FIG. 5B to FIG. 5C.

With reference to FIG. 5B, a photoresist layer 222 is formed on the substrate 220.

With reference to FIG. 5C, the photoresist layer 222 is patterned, the photoresist layer 222 is exposed and developed, a part of the photoresist layer 222 is dissolved, in which the undissolved part of the photoresist layer 222 forms a mask pattern 223. The mask pattern 223 includes a first window 223a. The first window 223a is a hollow pattern, and the first window 223a corresponds to the first trench 2021.

The surface of the substrate 220 exposed by the first window 223a is etched by using the mask pattern 223 as a mask layer to form the first trench 2021 shown in FIG.

In some embodiments, S103 “the bottom of the first trench is etched to form the second trench” includes the following operations.

At S131, the bottom of the first trench is etched by using the third insulating layer as a mask to form the second trench.

The above operation S131 is described below with reference to FIG. 4I and FIG. 6.

FIG. 4I is a schematic diagram illustrating the formation of the third insulating layer 303 on the side wall of the first trench 2021. Herein, the surface of the etched substrate 220 is exposed at the bottom 2021a of the first trench 2021. The bottom 2021a of the first trench 2021 is etched by using the third insulating layer 303 as a mask to form a second trench 2022 shown in FIG. 6.

In this case, since the second trench 2022 is formed by etching the surface of the substrate 220 exposed by the first trench 2021, the width w2 of the first trench is greater than the width w1 of the second trench 2022.

In some embodiments, the WL structure includes a WL conductive layer and a WL insulating layer. S30 “a WL structure is formed in the WL trench where the insulating structure is formed” includes the following operations as shown in FIG. 7A.

At S301, a WL conductive layer is formed in the WL trench where the insulating structure is formed.

Here, the WL conductive layer is formed in the WL trench where the insulating structure is formed by deposition. The material of the WL conductive layer may include metal and polysilicon. Herein, the metal material may include, but is not limited to, any combination of the conductive materials such as Wolframium (W), Cobalt (Co), Copper (Cu) and Aluminum (Al).

At S302, a WL insulating layer is formed on the WL conductive layer in the WL trench, in which the interface between the WL conductive layer and the WL insulating layer is higher than the stepped surface of the WL trench.

Here, the WL insulating layer may include, for example, oxide of silicon, silicon oxycarbide or silicon oxynitride. The WL insulating layer may be formed by LPCVD.

S301 to S302 are described below with reference to FIG. 7B to FIG. 7F.

With reference to FIG. 7B, a WL conductive layer 401 is deposited in the WL trench 202 where the insulating structure 30 is formed, the WL conductive layer 401 fills in the first trench 2021 and the second trench 2022, and the surface of the WL conductive layer 401 is flush with the upper surface of the substrate 220.

FIG. 7C is a schematic diagram obtained by cutting FIG. 7B along B-B and corresponding to a complete first trench.

With reference to FIG. 7D, the WL conductive layer 401 is etched so that the surface 40a of the etched WL conductive layer 401 is higher than the stepped surface 202d of the WL trench 202.

Then a WL insulating layer 50 shown in FIG. 7E and FIG. 7F is formed on the WL conductive layer 401 in the WL trench 202. In this case, with reference to FIG. 7F, the interface 40a between the WL conductive layer 401 and the WL insulating layer 50 is higher than the stepped surface 202d of the WL trench 202.

In the embodiment of the disclosure, the interface between the WL conductive layer and the WL insulating layer in the WL structure is set to be higher than the stepped surface of the WL trench, the insulating structure in the overlap area between the WL conductive layer and a NC or a BLC includes two insulating layers with different dielectric constants, and the two insulating layers with different dielectric constants are equivalent to a thicker insulating layer with a lower dielectric constant, so that the capacitance between the WL structure and other structures may be effectively reduced. When the above semiconductor structure is configured to form a DRAM, since a portion of the WL structure located in the active area also serves as a gate of the transistor, the above semiconductor structure may improve the on-off speed of the transistor and reduce the phenomenon of transistor leakage.

The embodiments of the disclosure further provide a method for forming a semiconductor structure, which includes the following operations.

At S401, a substrate 220 shown in FIG. 4C is provided.

At S402, with reference to FIG. 5B, a photoresist layer 222 is formed on the substrate 220.

At S403, the photoresist layer 222 is patterned to form a mask pattern 223 shown in FIG. 5C.

At S404, the substrate 220 is etched by using the mask pattern 223 as a mask to form a first trench 2021 shown in FIG. 4E and FIG. 4E

At S405, with reference to FIG. 4G, a fourth insulating layer 304 is formed in the first trench 2021 and on the substrate 220.

At S406, with reference to FIG. 4H, the fourth insulating layer 304 on the substrate 220 and at the bottom 2021a of the first trench 2021 is removed, in which the fourth insulating layer 304 on the side wall 202a of the first trench 2021 is retained to form a third insulating layer 303 shown in FIG. 4I.

At S407, the bottom 2021a of the first trench 2021 is etched by using the third insulating layer 303 as a mask to form a second trench 2022 shown in FIG. 6.

At S408, with reference to FIG. 3B, the surface of the third insulating layer 303 is oxidized to form a second insulating layer 302 shown in FIG. 2C. Herein, the unoxidized part of the third insulating layer 303 forms the first insulating layer 301.

At S409, with reference to FIG. 7B, a WL conductive layer 401 is formed in the WL trench 202 where the insulating structure 30 is formed.

At S410, with reference to FIG. 7D, the WL conductive layer 401 is etched so that the surface 40a of the etched WL conductive layer 401 is higher than the stepped surface 202d of the WL trench 202.

At S411, with reference to FIG. 7E and FIG. 7F, a WL insulating layer 50 is formed on the WL conductive layer 401 in the WL trench 202. The interface between the WL conductive layer 401 and the WL insulating layer 50 is higher than the stepped surface 202d of the WL trench 202.

The characteristics disclosed in the several method or structure embodiments provided in the present disclosure may be arbitrarily combined without conflict to obtain a new method embodiment or structure embodiment.

Descriptions about the above semiconductor structure embodiment are similar to descriptions about the method embodiment and beneficial effects similar to those of the method embodiment are achieved. Technical details undisclosed in the semiconductor structure embodiment of the disclosure are understood with reference to the descriptions about the method embodiment of the disclosure.

The above is only exemplary embodiments of the disclosure and not intended to limit the protection scope of the disclosure. Any modifications, equivalent replacements, improvements and the like made within the spirit and principle of the disclosure shall fall within the protection scope of the disclosure.

1. A method for forming a semiconductor structure, comprising:
providing a base, wherein the base comprises a Word Line (WL) trench with a stepped side wall, and a width of a top of the WL trench is greater than a width of a bottom of the WL trench;
forming an insulating structure on the side wall and a bottom wall of the WL trench; and
forming a WL structure in the WL trench where the insulating structure is formed.

2. The method of claim 1, wherein forming the insulating structure on the side wall and the bottom wall of the WL trench comprises:
conformally forming the insulating structure on the side wall and the bottom wall of the WL trench, wherein a thickness of the insulating structure at a top of the side wall is greater than a thickness of the insulating structure at a bottom of the side wall.

3. The method of claim 2, wherein the insulating structure comprises a first insulating layer and a second insulating layer,
wherein the first insulating layer at least covers the side wall of the WL trench above a stepped surface of the WL trench,
the second insulating layer covers a surface of the first insulating layer and a surface of the WL trench not covered by the first insulating layer.

4. The method of claim 3, wherein a thickness of the first insulating layer is greater than a thickness of the second insulating layer.

5. The method of claim 3, wherein conformally forming the insulating structure on the side wall and the bottom wall of the WL trench comprises:
forming a third insulating layer at least on the side wall of the WL trench above the stepped surface; and
at least oxidizing a surface of the third insulating layer to form the second insulating layer, wherein an unoxidized part of the third insulating layer forms the first insulating layer.

6. The method of claim 5, wherein at least oxidizing the surface of the third insulating layer to form the second insulating layer comprises:
in a case that the third insulating layer covers the side wall of the WL trench above the stepped surface and does not completely cover a surface of the WL trench, oxidizing a surface of the WL trench not covered by the third insulating layer and the surface of the third insulating layer to form the second insulating layer; or
in a case that the third insulating layer completely covers a surface of the WL trench, oxidizing the surface of the third insulating layer to form the second insulating layer.

7. The method of claim 5, wherein the WL trench comprises a first trench and a second trench which are stacked onto one another in a depth direction of the WL trench, wherein a width of the first trench is greater than a width of the second trench, and an interface between the first trench and the second trench is the stepped surface of the WL trench,
wherein forming the third insulating layer at least on the side wall of the WL trench above the stepped surface comprises:
forming the third insulating layer on a side wall of the first trench.

8. The method of claim 7, wherein providing the base comprises:
providing a substrate, and etching the substrate to form the first trench,
wherein forming the third insulating layer on the side wall of the first trench comprises: forming a fourth insulating layer in the first trench and on the substrate, and removing the fourth insulating layer on the substrate and at a bottom of the first trench, wherein the fourth insulating layer on the side wall of the first trench is retained to form the third insulating layer,
wherein providing the base further comprises:
etching the bottom of the first trench to form the second trench.

9. The method of claim 8, wherein etching the substrate to form the first trench comprises:
forming a photoresist layer on the substrate;
patterning the photoresist layer to form a mask pattern; and
etching the substrate by using the mask pattern as a mask to form the first trench.

10. The method of claim 8, wherein etching the bottom of the first trench to form the second trench comprises:
etching the bottom of the first trench by using the third insulating layer as a mask to form the second trench.

11. The method of claim 8, wherein forming the fourth insulating layer in the first trench and on the substrate comprises:
forming the fourth insulating layer in the first trench and on the substrate by atomic layer deposition.

12. The method of claim 1, wherein the WL structure includes a WL conductive layer and a WL insulating layer, wherein forming the WL structure in the WL trench where the insulating structure is formed comprises:
forming the WL conductive layer in the WL trench where the insulating structure is formed; and
forming the WL insulating layer on the WL conductive layer in the WL trench, wherein an interface between the WL conductive layer and the WL insulating layer is higher than a stepped surface of the WL trench.

13. The method of claim 7, wherein a depth of the first trench is ⅓ of a depth of the WL trench.

14. A semiconductor structure, comprising:
a base, wherein the base comprises a Word Line (WL) trench with a stepped side wall, and a width of a top of the WL trench is greater than a width of a bottom of the WL trench; and
an insulating structure formed on the side wall and a bottom wall of the WL trench, and a WL structure surrounded by the insulating structure.

15. The semiconductor structure of claim 14, wherein a thickness of the insulating structure at a top of the side wall is greater than a thickness of the insulating structure at a bottom of the side wall.

16. The semiconductor structure of claim 15, wherein the insulating structure comprises a first insulating layer and a second insulating layer,
wherein the first insulating layer at least covers the side wall of the WL trench above a stepped surface of the WL trench,
the second insulating layer covers a surface of the first insulating layer and a surface of the WL trench not covered by the first insulating layer.

17. The semiconductor structure of claim 16, wherein a thickness of the first insulating layer is greater than a thickness of the second insulating layer.

18. The semiconductor structure of claim 16, wherein the WL trench comprises a first trench and a second trench which are stacked onto one another in a depth direction of the WL trench, wherein a width of the first trench is greater than a width of the second trench, and an interface between the first trench and the second trench is the stepped surface of the WL trench,
wherein the first insulating layer covers a side wall of the first trench, and the second insulating layer covers the first insulating layer and a surface of the second trench.

19. The semiconductor structure of claim 18, wherein a depth of the first trench is ⅓ of a depth of the WL trench.

20. The semiconductor structure of claim 14, wherein the WL structure comprises a WL conductive layer and a WL insulating layer.
